(19) United States
(12) Patent Application Publication
(10) Pub. No.: US 2009/0032102 A1
(43) Pub. Date: Feb. 5, 2009

(54) Light collection device

(75) Inventors: Hon-Lun Chen, Taipei (TW); Kuo-Hsin Teng, Taipei (TW); Han-Yi Chang, Taipei (TW)

Correspondence Address: REED SMITH LLP, Suite 1400, 3110 Fairview Park Drive, Falls Church, VA, 22042, US

(73) Assignee: Prodisc Technology, Inc.

(21) Appl. No.: 12/222,102

(22) Filed: Aug. 1, 2008

(30) Foreign Application Priority Data
Aug. 3, 2007 (TW) 096128545

(51) Int. Cl. H01L 31/0232; F24J 2/08; G02B 6/32

(52) U.S. Cl. 136/259; 126/698; 385/33; 257/E31.127

(57) ABSTRACT

A light collection device assembled with a light-processing unit comprises a fresnel lens unit, an anti-reflection layer and a light-processing unit. The fresnel lens unit has a light-incident surface and a light-emitting surface. The light-processing unit is positioned with the light-emitting surface for transmitting or converting a light emitted from the fresnel lens unit. The anti-reflection layer is mounted or formed on the light-incident surface of the fresnel lens unit.

### BACKGROUND OF THE INVENTION

1. Technical Field

The present invention relates to a light collection device and, more particularly, to a light collection device that acts as a solar energy concentrator.

2. Description of Related Art

Solar energy is a natural, recyclable source of energy that can generate useful energy, such as electricity, through photoconversion. As solar energy is pollution-free, readily available and inexhaustible, it has become an important alternative energy source for human activities. However, conventional solar energy systems traditionally suffer from limitations such as requiring arrays that cover vast surface areas, and having low density and utilization rates. In addition, the efficiency of conventional solar energy systems in converting sunlight into electricity depends on numerous factors including but not limited to the materials used to construct the solar cells, the positioning of the solar array relative to the direction of the incoming sunlight, the amount of space or surface area available on which to mount the solar array, and the amount of sunlight available on a regular basis.

Thus, ideally, a light collection system or a light collection device is needed to convert solar energy, within an effective space, into light energy covering a small area and having a high density and utilization rate.

FIG. 1 illustrates a conventional light collection device 1 that comprises a light collection lens unit 11 and an optical fiber cable 13. The light collection device 1 is a solar concentrator, wherein the light collection lens unit 11 is a convex lens having a light-incident surface 111 and a light-emitting surface 112. Light L, such as sunlight, is concentrated after passing through the light-incident surface 111 and out of the light-emitting surface 112 of the convex lens. The concentrated light L is then directed to the optical fiber cable 13, and is delivered by the optical fiber 13 to an intended destination for photoelectric conversion.

However, since the light collection lens unit 11 of the conventional light collection device 1 is composed of a convex lens structure which may have flaws in the lens itself, not all of the light energy passing through the lens will be perfectly concentrated and projected into the optical fiber cable 13. Inevitably, a portion of the light passing through the lens will be reflected or refracted away from the intended optical fiber cable 13 during the light concentration process. In addition, conventional convex lenses for optical use are usually made of glass, and need to be ground and polished to form a desired shape, which can lead to high production costs, especially the more precise and complex is the process used to achieve the most ideal optical characteristics in the lens.

Therefore, it is important to design a light collection device that can prevent light passing therethrough from being reflected, refracted or backscattered, so as to increase the light collection efficiency of the light collection device.

### BRIEF SUMMARY OF THE INVENTION

In view of the above, it is an object of the present invention to provide a light collection device that can minimize the problems of reflection, refraction and backscattering of the inputted light to thereby enhance the light collection efficiency of the light collection device.

To achieve this end, the present invention provides a light collection device assembled with a light-processing unit, wherein the light collection device comprises a fresnel lens unit and an anti-reflection layer. The fresnel lens unit has a light-incident surface and a light-emitting surface, wherein the light-processing unit is disposed on the light-emitting surface for transmitting or converting light emitted from the fresnel lens unit. The anti-reflection layer is disposed on the light-incident surface.

As described above, the light collection device according to the present invention is provided with the fresnel lens unit while the light-incident surface thereof is coated with the anti-reflection layer to reduce reflection of light, so that the light enters the light-processing unit. Compared with conventional light collection devices, the light collection device according to the present invention has the advantages of reducing losses in the inputted light due to reflection or refraction, providing a better light condensation effect and enhancing light collection efficiency. Furthermore, a fresnel lens can be formed by injection molding or other molding techniques, which allows not only a variety of designs, but also mass production without requiring complex or precision manufacturing processes, thereby achieving lower production costs.

### BRIEF DESCRIPTION OF THE DRAWINGS

The invention as well as preferred modes of use, further objectives and advantages thereof will best be understood by reference to the following detailed description of illustrative embodiments when read in conjunction with the accompanying drawings, wherein:

FIG. 1 is a schematic view of a conventional light collection device;

FIG. 2A is a schematic view of a light collection device according to a first preferred embodiment of the present invention;

FIG. 2B is a cross-sectional view of one variation of the anti-reflection layer as applied to a light collection device according to a first preferred embodiment of the present invention;

FIG. 3A is a schematic view of a light collection device according to a second preferred embodiment of the present invention;

FIG. 3B is a schematic view of a light collection device according to a variation of the second preferred embodiment of the present invention;

FIG. 4A is one embodiment of the mounting structure between the fresnel lens unit and the light-processing unit of the light collection device;

FIG. 4B is a second embodiment of the mounting structure between the fresnel lens unit and the light-processing unit of the light collection device;

FIG. 4C is a third embodiment of the mounting structure between a plurality of fresnel lens unit and corresponding light-processing units of the light collection device;

FIG. 5A is a variation of the mounting structure between the fresnel lens unit and the light-processing unit of the light collection device that incorporates a convex lens;

FIG. 5B is a variation of the mounting structure between the fresnel lens unit and the light-processing unit of the light collection device that incorporates a concave lens;

FIG. 6 is a schematic view of a light collection device according to a third preferred embodiment of the present invention;

FIG. 7A illustrates the single focus point operation of the fresnel lens according to the present invention;

FIG. 7B illustrates the parallel beam operation of the fresnel lens according to the present invention; and

FIG. 8 illustrates a schematic view of a light collection device according to a fourth preferred embodiment of the present invention.

### DETAILED DESCRIPTION OF THE INVENTION

Light collection devices according to preferred embodiments of the present invention will now be described hereinbelow with reference to the accompanying drawings, wherein identical elements will be designated by the same reference numerals.

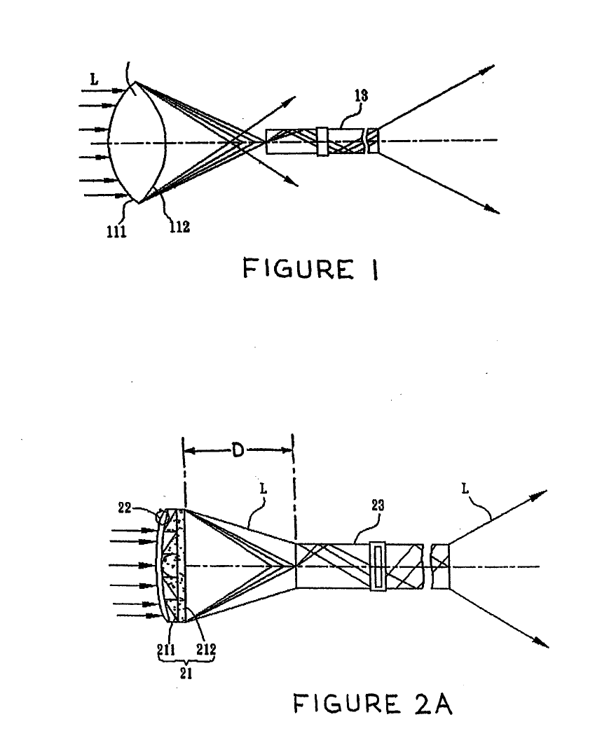

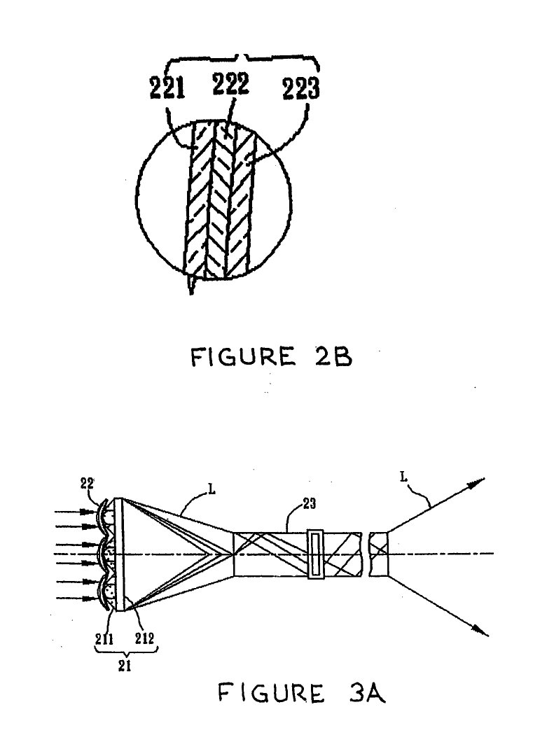

Referring to FIG. 2A, a light collection device 2 according to a first preferred embodiment of the present invention comprises a fresnel lens unit 21, an anti-reflection layer 22 and a light-processing unit 23. In this embodiment, the light collection device 2 is a solar concentrator configured to direct inputted solar energy or light onto a smaller specific spot or area.

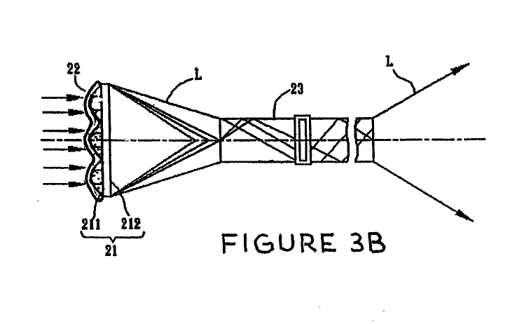

The fresnel lens unit 21 has a light-incident surface 211 and a light-emitting surface 212, wherein the light-incident surface 211 comprises at least one fresnel lens. More particularly, in terms of having different types of fresnel lens designs that are available, the light-incident surface 211 may comprise a single fresnel lens (see FIG. 2A), or an array consisting of a plurality of specifically arranged linear fresnel lenses or concentric fresnel lenses 211′, in which each of the fresnel lenses 211′ is designed and/or selected to have one or a plurality of focal lengths (see FIG. 3A), depending on its position in the array and its distance from the light-processing unit 23, including but not limited to linear or concentric fresnel lenses.

Referring to FIG. 2A, the anti-reflection layer 22 through which the light L, such as sunlight, passes, allows easy entrance of the light L into the fresnel lens unit 21, but makes reflection or backscattering thereof difficult, thereby enhancing light collection efficiency. The anti-reflection layer 22 may be formed as a single unit disposed over the entire light-incident surface 211 of the fresnel lens unit 21. In the case of FIG. 3A, the anti-reflection layer 22 is formed as a plurality of smaller anti-reflection layer elements 22′, each of which is formed and positioned to align with a corresponding one of the plurality of fresnel lenses 211′ so that different elements 22′ of the anti-reflection layer 22 together are disposed to conform with corresponding fresnel lenses 211′ of the surface of the light-incident surface 211. If the anti-reflection layer 22 is formed as a large single piece, the anti-reflection layer 22 may be adhered to the light-incident surface 211 by any conventional process including but not limited to adhesive glues and mounting hardware (i.e., mounting screws, clips, brackets).

Alternatively, as shown in FIG. 3B, the anti-reflection layer 22″ may be formed as a coating on the light-incident surface 211 so that different portions of the anti-reflection layer 22″ are disposed to conform with the surface contours or shape of the light-incident surface 211.

The anti-reflection layer 22 may comprise a single optical layer, or a plurality of optical sub-layers having different refractive indices. As shown in FIG. 2B, the anti-reflection layer 22 may be formed from optical sub-layers 221, 222 and 223, wherein each sub-layer has a refractive index formed, selected or modified to reduce unwanted reflection or refraction depending on the position of the corresponding portion of the fresnel lens unit 21, or the position of the corresponding fresnel lens element 211′ within the fresnel lens unit 21, or the design of the corresponding fresnel lens within the fresnel lens unit 21.

In the single-layer variation, the anti-reflection layer 22, 22′ or 22″ may be made of silicon dioxide (SiO₂), titanium dioxide (TiO₂), magnesium fluoride (MgF₂), fluorinated alkyl polyether compounds and salts thereof, or perfluoroalkyl ether compounds, or combinations of the above. In the multi-layer variation, each of the optical sub-layers 221, 222 and 223 may be formed using any of the above materials, whereby the anti-reflection layer 22, 22′ or 22″ may be a combination of two or more different materials, each having its own specific optical characteristics to contribute to the overall effect of the anti-reflection layer, including the combination of a silicon dioxide (SiO₂) layer and a titanium dioxide (TiO₂) layer. Each variation of the anti-reflection layer may also be formed from any combination of the above and other materials depending on the specific embodiment to which the anti-reflection layer is applied. For example, the anti-reflection layer 22 may be formed from one single material or from several layers of material that are bonded or adhered to each other (see FIG. 2B) in order to form a single construction. Alternatively, each anti-reflection layer element or portion 22′ may be formed from the same material, a different single material or several layers of different materials. The selection of whether to use a single material or several materials, or which combination or materials to use may be determined by the particular position of the fresnel lens 211′ within the array of plural fresnel lenses to which the anti-reflection layer element 22′ is associated, and the refractive index desired for that particular position of the fresnel lens 211′. As a further alternative, the anti-reflection layer 22″ may be formed as a single coating made from the same material or several coating layers of different materials. Here also, the selection of whether to use a single material or several materials, or which combination or materials to use may be determined by the specific area on the fresnel lens 211 on which the anti-reflection layer 22″ is coated and the refractive index desired at that area, or the particular position of the fresnel lens 211′ within the array of plural fresnel lenses to which the anti-reflection layer element 22′ is associated, and the refractive index desired for that particular position of the fresnel lens 211′.

It should be noted that the actual design and selection of the refractive index of the anti-reflection layer 22, 22′ or 22″ is relatively conventional so as to be known to those of skill in the art; thus, further description of the process for making the anti-reflection layers 22, 22′, 22″ or any of the optical sub-layers 221, 222 and 223 will be omitted herein.

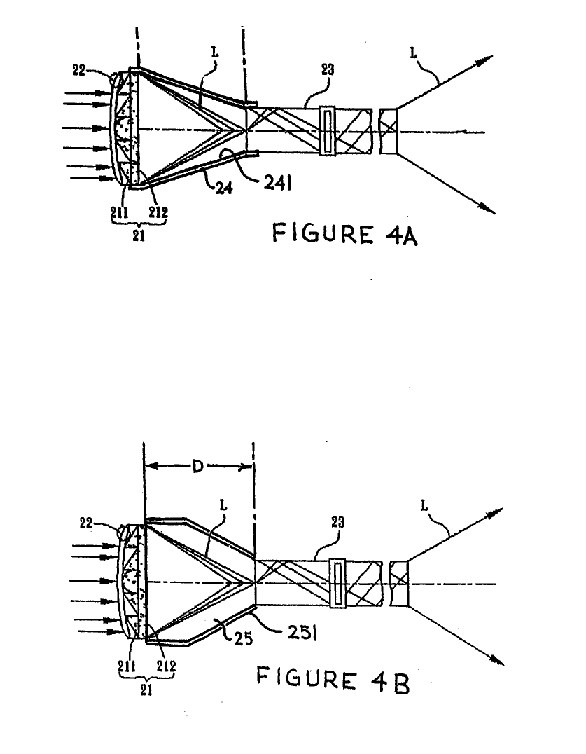

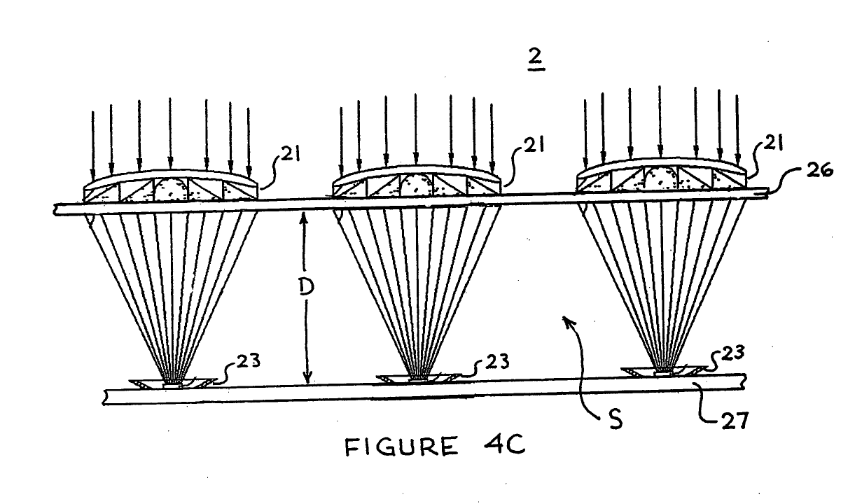

In the above-discussed embodiments, the light-processing unit 23 is assembled with the light collection device 2 and, more particularly, is fixedly positioned relative to the light-emitting surface 212 of the fresnel lens unit 21. In at least one embodiment, as shown in FIG. 4A, the light-processing unit 23 and the fresnel lens unit 21 are fixedly mounted in a casing 24 at a fixed distance D from each other. The distance D is determined so as to optimize the light collection from the fresnel lens unit 21 to the light-processing unit 23, while considering any constraints on the size and/or space available for the entire light collection device, as based on the specific application of the light collection device 2. In at least one embodiment, the distance D may be in the range of 1 mm to 1000 mm.

The casing 24 may be shaped and formed from an opaque material to prevent any light L from being directed away from the light-processing unit 23, such as a conical or pyramidal shape where the fresnel lens unit 21 is fixedly mounted at the larger end of the casing 24 and the light-processing unit 23 is fixedly mounted at the narrower or smaller end of the casing 24. In addition, the interior surface 241 of the casing 24 may be formed with a reflective or refractive surface to further direct light L from the fresnel lens unit 21 to the light-processing unit 23. Examples of the material for the reflective or refractive interior surface 241 of the casing 24 include Al, Ti, Ni, Cu, or any polished metal or metallic material. The interior of the casing 24 may be a vacuum or be filled with an inert gas such as nitrogen, oxygen, argon, carbon dioxide, or any gas that has a refractive index both greater than or equal to 1 and less than 2 (1≦x<2), and that is selected so as to at least not hinder but if possible enhance the transmission of light.

Alternatively, as shown in FIG. 4B, the light-processing unit 23 and the fresnel lens unit 21 are fixedly mounted on opposite sides of a light-pipe element 25 at a fixed distance D′ from each other, where the distance D′ is the length of the light-pipe element 25. As with the embodiment of the casing 24, the distance D′ is determined to optimize the light collection from the fresnel lens unit 21 to the light-processing unit 23, while considering any constraints on the size and/or space available for the entire light collection device, as based on the specific application of the light collection device 2. In at least one embodiment, the distance D′ may be in the range of 1 mm to 1000 mm. The material of the light-pipe element 25 may be selected from any of the conventional materials used to make light-pipes, including but not limited to any polished metal such as Al, Ti, Ni, Cu, or any plastic, polymer or polymer-like material such as polycarbonate and polymethyl methacrylate. The shape of the light-pipe element 25 is also selected to optimize and guide the transmission of the light L from the fresnel lens unit 21 to the light-processing unit 23, including a conical or pyramidal shape or variations thereof, where the fresnel lens unit 21 is fixedly mounted at the larger end of the light-pipe 25 and the light-processing unit 23 is fixedly mounted at the narrower or smaller end of the light-pipe 25. In the case of a light-pipe made from a plastic, polymer or polymer-like material, the outer surface 251 of the light-pipe 25 may be coated with a reflective or refractive material 252 to further direct light L from the fresnel lens unit 21 to the light-processing unit 23. Examples of the material for the reflective or refractive coating 252 include Ag, Au, Cu, Al, Ti, Ni, or any alloy combination of any of these materials.

As a further variation, the light collection device 2 as shown in FIG. 4C may be implemented as a plurality of fresnel lens units 21 that are positioned in a line or in an array and fixedly mounted in a frame 26. Beneath them would be a corresponding number of light-processing units 23 that are aligned to receive light L from an opposing fresnel lens unit 21. The light-processing units 23 are in turn mounted on a frame or substrate 27, and positioned at a distance D from the fresnel lens units 21 above them. The space S between the frame 26 having the fresnel lens units 21 and the substrate 27 having the light-processing units 27 may be used in a manner similar to the other embodiments described herein, including but not limited to being left open to the atmosphere, sealed in a vacuum, sealed with an inert gas, occupied with enclosures to direct the light L (see FIG. 3A) or occupied with light-pipes to direct the light L (see FIG. 3B).

In at least one embodiment, the light-processing unit 23 is an optical fiber cable positioned to receive and transmit the light L (see FIG. 2A). As noted above, the anti-reflection layer 22 through which the light L, such as sunlight, passes, allows easy entrance of the light L into the fresnel lens unit 21, but makes reflection thereof difficult, thereby enhancing light collection efficiency. After being collected and focused, the light L is directed at the light-processing unit 23 via the light-emitting surface 212 and is then transmitted by the optical fiber cable of the light-processing unit 23 to a photoelectric conversion unit (not shown), where the light L outputted from the light-processing unit 23 may be converted into electricity for immediate use or storage.

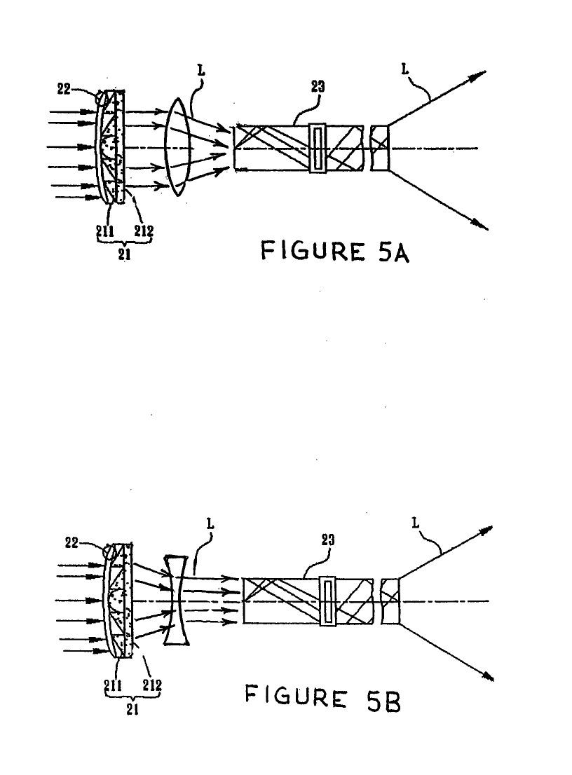

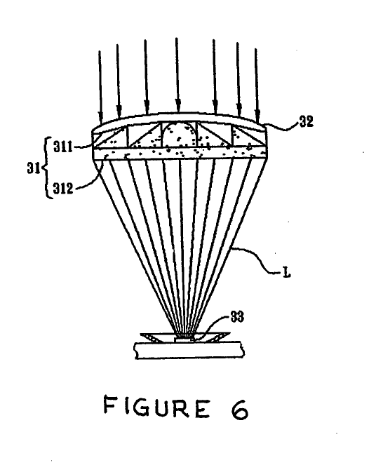

As a further enhancement for collecting and/or focusing the light L, as shown in FIG. 5A, a convex lens may be mounted between the fresnel lens unit 21 and the light-processing unit 23. Light L passing through the fresnel lens unit 21 approximately parallel are focused by the convex lens to converge onto a narrow area or a single point into the light-processing unit 23.

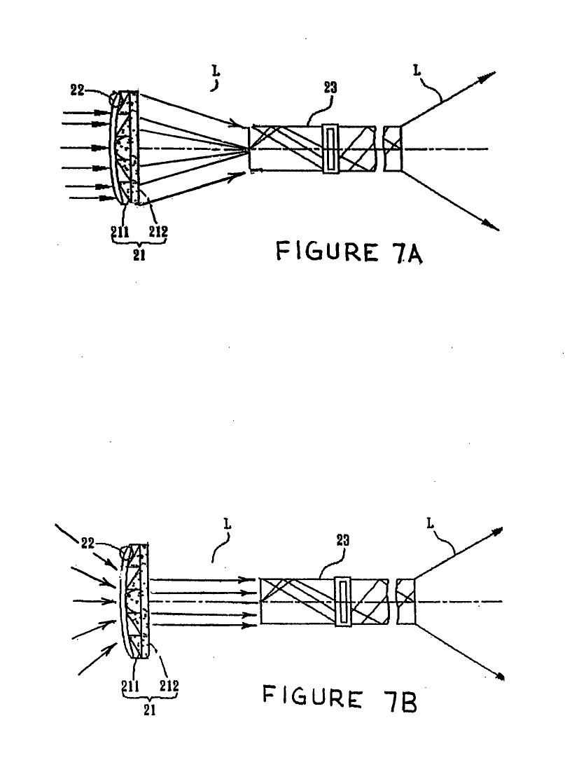

As shown in FIG. 5B, a concave lens instead may be mounted between the fresnel lens unit 21 and the light-processing unit 23. Light L passing through the fresnel lens unit 21 in a focused direction or at least in non-parallel vectors are focused by the concave lens into parallel vectors into the light-processing unit 23. A variation of either of these two structures would incorporate forming either the convex lens or the concave lens as the light-emitting surface 212 of the fresnel lens unit 21. Thus, the fresnel lens unit 21 in such an embodiment applicable to any and all of the other embodiments disclosed herein, would comprise at least the light-incident surface 211 having at least one fresnel lens and the light-emitting surface 212 having the convex or concave lens. Such structures would be one way of implementing, respectively, the single focus point and parallel beam operations illustrated in FIGS. 7A-7B as discussed hereinbelow.

Referring to FIG. 6, a light collection device 3 according to a third preferred embodiment of the present invention comprises a fresnel lens unit 31, an anti-reflection layer 32 and a light-processing unit 33, wherein the fresnel lens unit 31 and the anti-reflection layer 32 have technical features identical to those of the fresnel lens unit 21 and the anti-reflection layer 22 in the previous preferred embodiments, so that a description thereof is omitted herein. The light collection device 3 differs from the light collection device 2 in the previous preferred embodiments of the present invention in that the light-processing unit 33 is a solar cell unit or a photoconverter unit. The light L passing through the anti-reflection layer 32 and the fresnel lens unit 31 is condensed directly on the solar cell unit where photoelectric conversion takes place.

As with the previous embodiments, the mounting structure for the embodiment shown in FIG. 6 may be implemented using the casing 24 or the light-pipe 25 (see FIGS. 3A and 3B, respectively). In the case of the light-pipe 25, the shape of the light pipe may be selected to further distribute the light L uniformly over the entire surface of the light-processing unit 33, thereby further enhancing efficiency in the collection of light and photoelectric conversion.

The fresnel lens unit 21 or 31, depending on the type of light-processing unit 23 or 33, would be designed to concentrate the light L either into a single focus point (see FIG. 7A) or to transmit the light L as parallel beams (see FIG. 7B). In accordance with the above-described embodiments, the single focus point design and operation of the fresnel lens unit 21,31 would be in accordance with the light-processing unit being a single fibre-optic cable (see FIG. 2A), a small bundle of fibre-optic cables or a small solar cell unit (see FIG. 6). The parallel beam design and operation of the fresnel lens unit 21,31 would be in accordance with the light-processing unit being a large bundle of fibre-optic cables or an array of solar cell units.

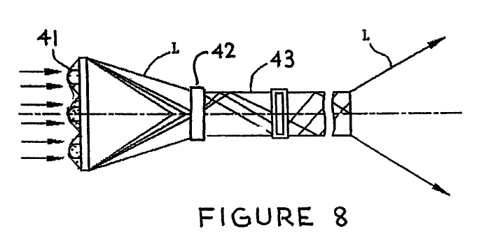

FIG. 8 illustrates a further embodiment of the present invention wherein the light collection device 4 is composed of a fresnel lens unit 41, a light-processing unit 43 and an anti-reflection layer 42 mounted with the light-processing unit 43. The light L passes through the fresnel lens unit 41 and then through the anti-reflection layer 42 to allow easy entrance of the light L into the light-processing unit 43, but make reflection or backscattering thereof difficult, thereby enhancing light collection efficiency. The anti-reflection layer 42 may be formed as a single unit disposed over the light-processing unit 43. As with the above-described other embodiments, the anti-reflection layer 42 may be formed as a large single piece adhered to the light-processing unit 43 by any conventional process including but not limited to adhesive glues and mounting hardware (i.e., mounting screws, clips, brackets).

Alternatively, the anti-reflection layer 42 may be formed as a coating on the light-processing unit 43. Further, the anti-reflection layer 42 may comprise a single optical layer, or a plurality of optical sub-layers having different refractive indices, such as that shown in FIG. 4B. The material and composition of the single-layer variation of multi-layer variation of the anti-reflection layer 42 would be consistent with the various embodiments of the anti-reflection layers 22, 32 described hereinabove, and thus further discussion thereof will be omitted.

In summary, the light collection device according to the present invention is provided with the fresnel lens unit while the light-incident surface thereof is coated with the anti-reflection layer to reduce reflection of light, so that the light enters the light-processing unit. Compared with the conventional light collection device, the light collection device according to the present invention is advantageous in reducing a loss of light due to reflection and backscattering, providing a better light condensation effect and enhancing a light collection efficiency. Furthermore, the fresnel lens can be formed by injection molding or molding, which allows not only a variety of designs, but also mass production that lowers production costs.

The present invention has been described with preferred embodiments thereof, which are provided for illustrative purposes only and not intended to limit the scope of the present invention. Moreover, as the content disclosed herein should be readily understood and can be implemented by a person skilled in the art, all equivalent changes or modifications which do not depart from the spirit of the present invention are encompassed by the appended claims.

What is claimed is:

1. A light collection device assembled with a light-processing unit, comprising:
a fresnel lens unit, having a light-incident surface and a light-emitting surface, wherein the light-processing unit is positioned relative to the light-emitting surface for receiving light from the fresnel lens unit and for further transmitting or converting the light; and
an anti-reflection layer positioned on the light-incident surface of the fresnel lens unit.

2. The light collection device as claimed in claim 1, wherein the fresnel lens unit comprises at least one fresnel lens.

3. The light collection device as claimed in claim 2, wherein the at least one fresnel lens is a linear fresnel lens or a concentric fresnel lens.

4. The light collection device as claimed in claim 1, wherein the fresnel lens unit comprises a plurality of fresnel lens.

5. The light collection device as claimed in claim 1, wherein the anti-reflection layer is formed from a plurality of optical sub-layers.

6. The light collection device as claimed in claim 5, wherein each of said optical sub-layers has a different refractive index from each other.

7. The light collection device as claimed in claim 1, wherein the anti-reflection layer is made from one of silicon dioxide (SiO₂), titanium dioxide (TiO₂), magnesium fluoride (MgF₂), fluorinated alkyl polyether compounds, or perfluoroalkyl ether compounds and salts thereof.

8. The light collection device as claimed in claim 1, wherein the anti-reflection layer is a coating formed on the light-incident surface.

9. The light collection device as claimed in claim 1, wherein the light-processing unit is one of an optical fiber cable, a solar cell unit and a photoconverter unit.

10. The light collection device as claimed in claim 1, wherein the light collection device is a solar concentrator.

11. A light collection device, comprising:
a fresnel lens unit, having a light-incident surface and a light-emitting surface;
an anti-reflection layer positioned on the light-incident surface of the fresnel lens unit; and
a light-processing unit positioned relative to the light-emitting surface for receiving light from the fresnel lens unit and for further transmitting or converting the light.

12. The light collection device as claimed in claim 11, wherein the fresnel lens unit comprises a plurality of fresnel lens arranged as an array.

13. The light collection device as claimed in claim 11, wherein the anti-reflection layer is formed from a plurality of optical sub-layers.

14. The light collection device as claimed in claim 13, wherein each of said optical sub-layers has a different refractive index from each other.

15. The light collection device as claimed in claim 11, wherein the anti-reflection layer is made from one of silicon dioxide (SiO₂), titanium dioxide (TiO₂), magnesium fluoride (MgF₂), fluorinated alkyl polyether compounds, or perfluoroalkyl ether compounds and salts thereof.

16. The light collection device as claimed in claim 11, wherein the anti-reflection layer is a coating formed on the light-incident surface.

17. The light collection device as claimed in claim 11, wherein the light-processing unit is one of an optical fiber cable, a solar cell unit and a photoconverter unit.
